(19) United States
(12) Patent Application Publication
(10) Pub. No.: US 2026/0305133 A1
(43) Pub. Date: Oct. 1, 2026

(54) DISPLAY PANEL AND FABRICATION METHOD THEREOF

(71) Applicant: HKC CORPORATION LIMITED, Shenzhen, Guangdong (CN)

(72) Inventors: Yangchuan Zhou, Shenzhen, Guangdong (CN); Lei Jiang, Shenzhen, Guangdong (CN); Haijiang Yuan, Shenzhen, Guangdong (CN)

(21) Appl. No.: 19/477,127

(22) PCT Filed: Oct. 28, 2023
(86) PCT No.: PCT/CN2023/127436

§ 371 Date: Oct. 21, 2025

(30) Foreign Application Priority Data
May 11, 2023 (CN) 202310526531.3

(51) Int. Cl. H10K 59/80; H10K 59/12; H10K 59/122; H10K 59/131; H10K 102/00

(52) U.S. Cl. CPC H10K 59/873; H10K 59/1201; H10K 59/122; H10K 59/1315; H10K 2102/351

(57) ABSTRACT

A display panel, including: a substrate; a driving circuit layer, located on a side of the substrate; an anode film layer, including a plurality of sub-anode film layers arranged at intervals on a side of the driving circuit layer away from the substrate a pixel definition layer which is arranged between adjacent two of the plurality of sub-anode film layers; a conductive layer, arranged on a side of pixel definition layer away from the substrate an insulating layer, arranged on a side of the conductive layer away from the pixel definition layer, protruding out from an edge of the conductive layer, and being a heat-shrinkable structure layer; an organic light-emitting layer, arranged on the anode film layer and the pixel definition layer; a cathode film layer, arranged on the organic light-emitting layer and covering a part of a lateral side of the conductive layer; and an inorganic encapsulation layer.

### CROSS-REFERENCE TO RELATED APPLICATIONS

This application is the U.S. national phase of International Application No. PCT/CN2023/127436 with an international filing date of Oct. 28, 2023, designating the U.S., now pending, and claims the priority of the Chinese patent application submitted to the CNIPA on May 11, 2023, with an application number 202310526531.3 and titled “DISPLAY PANEL AND FABRICATION METHOD THEREOF”, the entire contents of which are incorporated by reference in this application.

### BACKGROUND

### Technical Field

This application relates to the technical field of display panels, and more particularly to a display panel and a fabrication method thereof.

### Description of Related Art

An organic electroluminescent display device, such as an organic light-emitting diode (OLED) display, has the characteristics of automatic luminescence, wide viewing angle, fast response, small thickness, high contrast, etc. Therefore, as a next generation of the flat panel display device, the organic electroluminescent device has been widely used in the mobile phones, tablets and even computer display panels. Generally, an OLED display panel includes multiple pixels for emitting light of different colors, and multiple pixels emit light to display images. Each pixel is composed of red, green, and blue sub-pixels superimposed and mixed to realize the display of a white picture, and different color pictures are displayed by controlling the luminescence degree of sub-pixels of different colors.

A three-color light-emitting device can be fabricated by the following three current methods: a first method is to use a fine metal mask plate as a mask to deposit three-color light-emitting devices separately, a second method is to use inkjet printing to print the three-color light-emitting devices separately, and the third method is to use photolithography to etch the three-color light-emitting devices on the entire substrate after film formation. A current commonly used technology adopts the first method. However, as the pixel density unit (pixels per inch, PPI) of the display panel increases, the metal mask cannot take a better effect, and the use of photolithography technology to etch patterns has become a topic of in-depth research in the industry.

In the prior art, the use of photolithography technology to fabricate the light-emitting device has the following problems: when preparing the cathode film layer, due to the restriction of the end of the insulating layer, the contact area between the cathode film layer and the conductor is restricted, resulting in a large resistance at the contact region between the cathode film layer and the conductor, resulting in a voltage drop and affecting the display effect. During the encapsulation process, the inorganic encapsulation layer will also be restricted by the end of the insulating layer, resulting in poor protection of the covered inorganic encapsulation layer and the problem of cracks.

It is one of objects of embodiments of the present application to provide a display panel and a fabrication method thereof, so as to achieve better conduction between the cathode film layer and the conductor and improve the strength of the inorganic encapsulation layer.

### SUMMARY

In order to solve the above technical problems, embodiments of the present application adopt the following technical solutions:

A first aspect of the present application provides a display panel, which comprises:
a substrate;
a driving circuit layer, which is located on a side of the substrate;
an anode film layer, which comprises a plurality of sub-anode film layers arranged at intervals on a side of the driving circuit layer away from the substrate;
a pixel definition layer, which is arranged between adjacent two of the plurality of sub-anode film layers;
a conductive layer, which is arranged on a side of pixel definition layer away from the substrate;
an insulating layer, which is arranged on a side of the conductive layer away from the pixel definition layer, has a part thereof protruding out from an edge of the conductive layer to form an eave structure, and is a heat-shrinkable structure layer;
an organic light-emitting layer, which is arranged on the anode film layer and the pixel definition layer;
a cathode film layer, which is arranged on the organic light-emitting layer and covers a part of a lateral side of the conductive layer, has a part thereof located within a projection area of the insulating layer along a thickness direction of the insulating layer; and
an inorganic encapsulation layer, which is arranged on the cathode film layer and the conductive layer.

Optionally, a width of a side of the insulating layer away from the conductive layer is greater than a width of a side of the insulating layer close to the conductive layer.

Optionally, a cross section of the insulating layer in a thickness direction of the insulating layer is a trapezoid, and a width of the insulating layer gradually increases in a direction away from the conductive layer.

Optionally, a lateral side of the insulating layer is an inclined surface having an inclination angle of 20° to 70°.

Optionally, the heat-shrinkable structure layer comprises a heat-shrinkable material, and the heat-shrinkable material comprises at least one of antimony, bismuth, gallium, bronze, scandium trifluoride, an oxide or a fluoride of antimony, an oxide or a fluoride of bismuth, an oxide or a fluoride of gallium, an oxide or a fluoride of bronze, and a heat-shrinkable polymer material.

Optionally, the heat-shrinkable polymer material comprises at least one of a polyvinyl chloride, a polyethylene, a polypropylene, a polyester, and a silicone rubber.

Optionally, a width of the part of the insulating layer protruding out from the edge of the conductive layer is 0.2 μm to 1 μm.

Optionally, the lateral side of the conductive layer is an inclined surface.

Optionally, the lateral side of the conductive layer is an inclined surface which is inclined toward a side of the insulating layer, and a connection region between the cathode film layer and the conductive layer is located on the inclined surface.

Optionally, the display panel further comprises an organic encapsulation layer and a second inorganic encapsulation layer; the organic encapsulation layer is arranged on sides of the inorganic encapsulation layer and the insulating layer away from the substrate; and the second inorganic encapsulation layer is arranged on a side of the organic encapsulation layer away from the substrate.

Optionally, the display panel further comprises a cover plate; and the inorganic encapsulation layer, the organic encapsulation layer, the second inorganic encapsulation layer, and the cover plate are arranged in sequence in a direction away from the substrate.

A second aspect of the present application provides a fabrication method for a display panel. The fabrication method comprises:
providing a substrate;
preparing a driving circuit layer on a side of the substrate;
preparing an anode film layer on a side of the driving circuit layer away from the substrate, and etching the anode film layer to obtain a plurality of sub-anode film layers arranged at intervals;
preparing a pixel definition layer between adjacent two of the plurality of sub-anode film layers;
sequentially preparing a conductive layer and an insulating layer on the pixel definition layer, in which, a part of the insulating layer protrudes out from an edge of the conductive layer, and the insulating layer is a heat-shrinkable structure layer;
preparing an organic light-emitting layer on the anode film layer and the pixel definition layer by evaporation;
controlling a temperature of the heat-shrinkable structure layer to shrink the heat-shrinkable structure layer and still remain a part of the heat-shrinkable structure layer protrude out from the edge of the conductive layer, and preparing a cathode film layer on the organic light-emitting layer and the conductive layer; and
preparing an inorganic encapsulation layer on the cathode film layer and the conductive layer.

Optionally, before forming the cathode film layer, the heat-shrinkable structure layer is subjected to a heating treatment to shrink the heat-shrinkable structure layer.

Optionally, a film formation angle when preparing the organic light-emitting layer is smaller than a film formation angle when preparing the cathode film layer.

Optionally, a temperature of the insulating layer in preparation of the organic light-emitting layer is lower than a temperature of the insulating layer in preparation of the cathode film layer.

Optionally, after the heat shrinkage of the insulating layer, a width of the part of the insulating layer protruding out from the edge of the conductive layer is 0.2 μm to 1 μm.

Optionally, the step of sequentially preparing the conductive layer and the insulating layer on the pixel definition layer comprises:
covering the sub-anode film layer and the pixel definition layer with a pre-conductive layer, a pre-insulating layer, and a pre-protective layer stacked in sequence;
performing local dry etching on the pre-protective layer to obtain a protective layer corresponding to the pixel definition layer;
performing wet etching on the pre-insulating layer to obtain the insulating layer located between the protective layer and the pre-conductive layer;
performing wet etching on the pre-conductive layer to obtain the conductive layer located between the insulating layer and the pixel definition layer; and
removing the protective layer.

The beneficial effects of the display panel provided by embodiments of the present application are summarized as follows: the display panel provided by the present application includes the substrate, the driving circuit layer, the anode film layer, the pixel definition layer, the conductive layer, the insulating layer, the organic light-emitting layer, the cathode film layer, and the inorganic encapsulation layer. The insulating layer is arranged on a side of the conductive layer away from the pixel definition layer, so that the insulating layer can protect the conductive layer; meanwhile, a part of the insulating layer protrudes from the edge of the conductive layer, and it can be understood that the insulating layer will form a shielding for at least a part of a lateral side of the conductive layer. Further, the cathode film layer is arranged on the organic light-emitting layer, and the cathode film layer covers a part of the lateral side of the conductive layer, so that the cathode film layer and the conductive layer can achieve conductivity, and meanwhile, a part of the cathode film layer is located within the projection area of the insulating layer along the thickness direction of the insulating layer, that is, a part of the cathode film layer is located within the shielding region of the insulating layer, so that in the fabrication process of the display panel, due to the shielding effect of the insulating layer, the etching process (such as dry etching) after the formation of the cathode film layer will not damage the part of the cathode film layer arranged on the lateral side of the conductive layer and within the projection area of the insulating layer, thereby ensuring good electrical contact between the cathode film layer and the conductive layer. In addition, the insulating layer is a heat-shrinkable structure layer, that is, the insulating layer has the heat-shrinkable characteristic. In the fabrication process of the display panel, an insulating layer is usually prepared on the conductive layer firstly, and then a cathode film layer is prepared on the organic light-emitting layer. When preparing the cathode film layer, the temperature can be controlled to make the insulating layer shrink, so that the projection area of the insulating layer on the lateral side of the conductive layer becomes smaller, and then the cathode film layer is covered on the organic light-emitting layer and the lateral side of the conductive layer. As the projection area becomes smaller, the region covered by the cathode film layer on the lateral side of the conductive layer will become larger, that is, the contact surface between the cathode film layer and the conductive layer becomes larger, thereby improving the effect of electrical connection between the cathode film layer and the conductive layer. Moreover, due to the smaller projection area, a difference between a thickness of the inorganic encapsulation layer covering the conductive layer and a thickness of the inorganic encapsulation layer covering the cathode film layer 1becomes smaller, such that the inorganic encapsulation layer has greater strength, is less likely to generate cracks, and can provide a better encapsulation effect.

The beneficial effects of the fabrication method of the display panel provided by the present application are summarized as follows: compared with the prior art, the present application adopts a heat-shrinkable structure layer as the insulating layer, and utilizes the heat generated when the organic light-emitting layer is evaporated to heat the insulating layer, so that the insulating layer shrinks under the heat, which increases the contact area between the cathode film layer and the conductive layer, reduces the contact resistance between the cathode film layer and the conductive layer, and increases the coverage area and coverage thickness of the inorganic encapsulation layer on the conductive layer, thereby providing better protection performance for the display panel, and realizing a better encapsulation effect.

### BRIEF DESCRIPTION OF THE DRAWINGS

In order to more clearly illustrate the technical solutions in the embodiments of the present application, the drawings that need to be used in the description of the embodiments will be briefly described hereinbelow. Obviously, the accompanying drawings in the following description are only some embodiments of the present application. For those skilled in the art, other drawings can be obtained based on these drawings without creative work.

FIG. 1 is a structural schematic diagram of a display panel provided by a first embodiment of the present application;

FIG. 2 is a structural schematic diagram of the display panel provided by the first embodiment of the present application before shrinkage of an insulating layer;

FIG. 3 is a structural schematic diagram of the display panel provided by the first embodiment of the present application after the shrinkage of the insulating layer;

FIG. 4 is a comparative schematic diagram of the display panel provided by the first embodiment of the present application before and after shrinkage of the insulating layer;

FIG. 5 is a structural schematic diagram of a display panel provided by a second embodiment of the present application, in which the encapsulation layer is not shown;

FIG. 6 is a comparative schematic diagram showing the insulating layer in the display panel provided by the second embodiment of the present application and an existing insulating layer;

FIG. 7 is a partial schematic diagram of the display panel provided by the first embodiment of the present application; and

FIG. 8 is a flow schematic diagram of a fabrication method of a display panel provided by a third embodiment of the present application.

In the drawings, the following reference numerals are adopted:
Substrate 10; driving circuit layer 11; anode film layer 12; sub-anode film layer 120; pixel definition layer 13; conductive layer 14; pre-conductive layer 140; insulating layer 15; pre-insulating layer 150; organic light-emitting layer 16; cathode film layer 17; inorganic encapsulation layer 18; organic encapsulation layer 19; second inorganic encapsulation layer 20; cover plate 21; protective layer 22; and pre-protective layer 220.

### DETAILED DESCRIPTION OF THE EMBODIMENTS

In order to make the technical problems, technical solutions, and beneficial effects to be solved by the present application clearer, the present application is further described in detail in combination with the accompanying drawings and embodiments. It should be understood that the specific embodiments described herein are only used to explain the present application and are not intended to limit the present application.

It should be noted that when an element is referred to as “fixed on” or “arranged on” another element, the element can be directly on the other element or indirectly on the other element. When an element is referred to as “connected to” another element, the element can be directly connected to the other element or indirectly connected to the other element.

It should be understood that the orientation or position relationship indicated by the terms “length”, “width”, “upper”, “lower”, “front”, “back”, “left”, “right”, “vertical”, “horizontal”, “top”, “bottom”, “inside”, “outside” and the like are based on the orientation or position relationship shown in the accompanying drawings, and is only for the convenience of describing the present application and simplifying the description, rather than indicating or implying that the device or element referred to must have a specific orientation, be constructed and operated in a specific orientation, and therefore cannot be understood as a restriction on the present application.

In addition, the terms “first” and “second” are only used for descriptive purposes and cannot be understood as indicating or implying relative importance or implicitly indicating the number of technical features indicated. Thus, a feature defined as “first” or “second” may explicitly or implicitly include one or more of the features. In the description of this application, “plurality” means two or more, unless otherwise clearly and specifically defined.

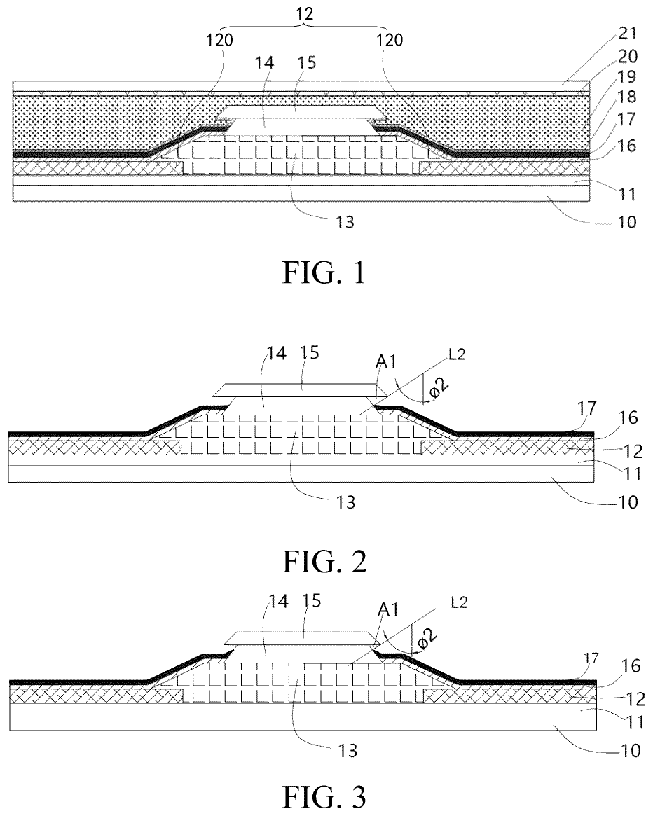

Referring to FIG. 1, which is a structural schematic diagram of a display panel provided by a first embodiment of the present application. The display panel provided by the present application is described hereinbelow.

The present application provides a display panel, as shown in FIG. 1, comprising:
a substrate 10;
a driving circuit layer 11, which is located on a side of the substrate;
an anode film layer 12, which comprises a plurality of sub-anode film layers 120 arranged at intervals on a side of the driving circuit layer 11 away from the substrate 10;
a pixel definition layer 13, which is arranged between adjacent two of the plurality of sub-anode film layers 120;
a conductive layer 14, which is arranged on a side of pixel definition layer 13 away from the substrate 10;
an insulating layer 15, which is arranged on a side of the conductive layer 14 away from the pixel definition layer 13, has a part thereof protruding out from an edge of the conductive layer 14 to form an eave structure, and is a heat-shrinkable structure layer;
an organic light-emitting layer 16, which is arranged on the anode film layer 12 and the pixel definition layer 13;
a cathode film layer 17, which is arranged on the organic light-emitting layer 16 and covers a part of a lateral side of the conductive layer 14, has a part thereof located within a projection area of the insulating layer 15 along a thickness direction of the insulating layer 15; and
an inorganic encapsulation layer 18, which is arranged on the cathode film layer 17 and the conductive layer 14.

In the prior art, in the fabrication process for a light-emitting device by using photolithography technology, because a whole-surface film forming method is adopted, an organic light-emitting layer 16 and a cathode film layer 17 are arranged above both the anode film layer 12 and the insulating layer 15. However, the insulating layer 15 is indispensable and functions in disconnecting the organic light-emitting layer 16 and the cathode film layer 17 and covering ends of the cathode layer and the organic light-emitting layer so as to protect them from the influence of subsequent processes (such as etching processes).

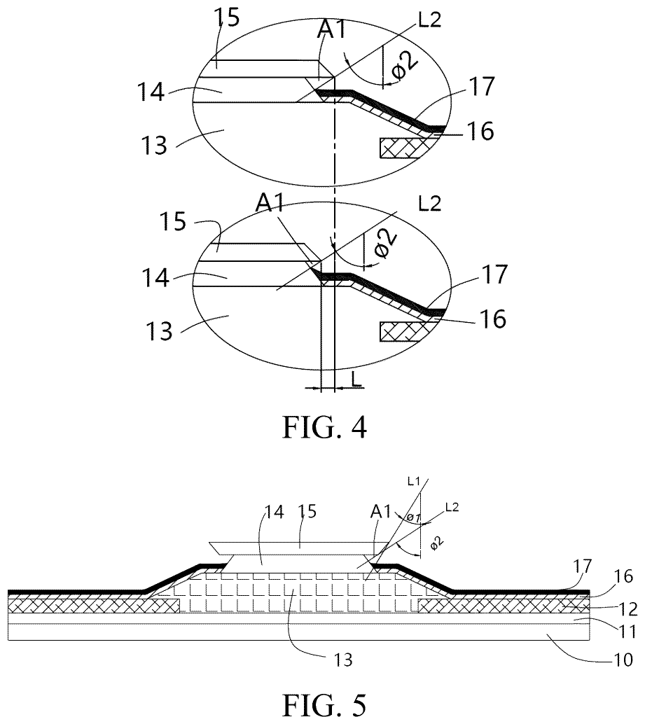

Referring to FIGS. 2-4, in which, FIG. 2 is a structural schematic diagram before the insulating layer shrinks, FIG. 3 is a structural schematic diagram after the insulating layer shrinks, and FIG. 4 is a comparative schematic diagram of the display panel provided in the first embodiment of the present application before and after the shrinkage of the insulating layer, L2 is a film-forming boundary line of the cathode film layer 17, and ø2 is a film formation angle of the cathode film layer 17. A region A1 is a region where the cathode film layer 17 cannot be deposited due to the shielding of the insulating layer 15. The insulating layer 15 is a heat-shrinkable structure layer, that is, the insulating layer 15 has heat-shrinkable characteristics. In the fabrication process of the display panel, an insulating layer 15 is usually prepared on the conductive layer 14 firstly, and then a cathode film layer 17 is prepared on the organic light-emitting layer 16. When preparing the cathode film layer 17, the insulating layer 15 can be shrunk by controlling the temperature. As shown in FIG. 4, when the insulating layer 15 is heated, an end of the insulating layer 15 shrinks toward a middle thereof by a distance L, so that a width of the part of the insulating layer 15 protruding out from the edge of the conductive layer 14 becomes narrower. In the process of preparing the cathode film layer 17, since the film formation angle ø2 of the cathode film layer 17 remains unchanged, an area of the region A1 becomes smaller, and a contact area between the cathode film layer 17 and the conductive layer 14 becomes larger, which reduces an contact resistance between the cathode film layer 17 and the conductive layer 14, so that a potential on the cathode film layer 17 is consistent with a potential provided by the driving circuit layer 11, thereby ensuring a good display effect. Moreover, due to the smaller projection area, a difference between a thickness of the inorganic encapsulation layer 18 covering the conductive layer 14 and a thickness of the inorganic encapsulation layer 18 covering the cathode film layer 17 becomes smaller, such that the inorganic encapsulation layer 18 has greater strength, is less likely to generate cracks, and can provide a better encapsulation effect.

In some embodiments of the present application, as shown in FIGS. 2-3, the lateral side of the insulating layer 15 is constructed to be an inclined surface, and the inclined surface faces a direction away from the conductive layer 14. Optionally, the lateral side of the insulating layer 15 can also be constructed to be a straight surface.

Referring to FIG. 5, which is a structural schematic diagram of the display panel provided in a second embodiment of the present application. In some embodiments of the present application, a width of a side of the insulating layer 15 away from the conductive layer 14 is greater than a width of a side of the insulating layer 15 close to the conductive layer 14.

In some embodiments of the present application, a cross section of the insulating layer 15 in a thickness direction thereof is a trapezoid, and the width of the insulating layer 15 gradually increases in a direction away from the conductive layer 14.

In other embodiments of the present application, a cross section of the insulating layer 15 along the thickness direction thereof may also be step-shaped, and the width of the insulating layer 15 increases gradually in the direction away from the conductive layer 14.

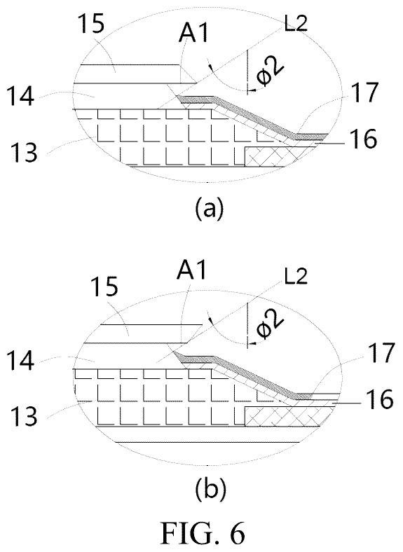

Referring to FIG. 6, which is a comparative schematic diagram of structures of the insulating layer in the display panel provided by the second embodiment of the present application and the insulating layer provided by the first embodiment. Part (a) of FIG. 6 shows the insulating layer provided by the first embodiment, from which, it can be seen that the insulating layer provided by the first embodiment is small at the top and large at the bottom (referring to the direction as shown in this figure), and the film-forming boundary line L2 of the cathode film layer 17 is restricted by a lower plane endpoint of the insulating layer 15. Part (b) of FIG. 6 shows the insulating layer 15 in the second embodiment, from which, it can be seen that the cross-sectional shape of the insulating layer 15 is a trapezoid, and the width of the insulating layer 15 gradually increases in the direction away from the conductive layer 14. After adopting the insulating layer 15 provided by the second embodiment of the present application, the film-forming boundary line L2 of the cathode film layer 17 is also restricted by the lower plane endpoint of the insulating layer 15, but compared with the lower plane endpoint of the insulating layer 15 in the first embodiment, its distance from the conductive layer 14 is reduced, which reduces the area of the region A1, and can further increase the contact area between the cathode film layer 17 and the conductive layer 14, thereby reducing the contact resistance and improving the display effect.

As shown in part (b) of FIG. 6, the lateral side of the insulating layer 15 is constructed to be an inclined plane which is inclined toward the conductive layer 14, which can reduce the restriction of the lower plane endpoint of the insulating layer 15 on the film-forming boundary line L2 of the cathode film layer 17. When the width of the insulating layer 15 protruding out from the conductive layer 14 remains unchanged, as the inclination angle of the inclined plane (that is, the angle between the inclined plane and the vertical plane) increases, the restriction of the lower plane endpoint of the insulating layer 15 on the film-forming boundary line L2 of the cathode film layer 17 gradually decreases. When the inclination angle of the lateral side of the insulating layer 15 is the same as the film formation angle ø2 of the cathode film layer 17 (that is, the film-forming boundary line L2 of the cathode film layer 17 is located in the plane where the inclined plane is located), in such condition, the area of the region A1 is minimized.

In other embodiments of the present application, the inclination angle of the lateral side of the insulating layer 15 is greater than the film formation angle ø2 of the cathode film layer 17. In such condition, the lower plane endpoint of the insulating layer 15 no longer restricts the film-forming boundary line L2 of the cathode film layer 17, and the area of the region A1 is also minimized.

In some embodiments of the present application, the lateral side of the insulating layer 15 is an inclined plane, and the inclination angle of the inclined plane is any angle between 20° and 70°, for example, 20°, 30°, 40°, 50°, 60°, 70°, and the like, which is not limited in the present application. The film formation angle ø2 can be adjusted to be the same as the inclination angle of the inclined plane by adjusting the film formation device.

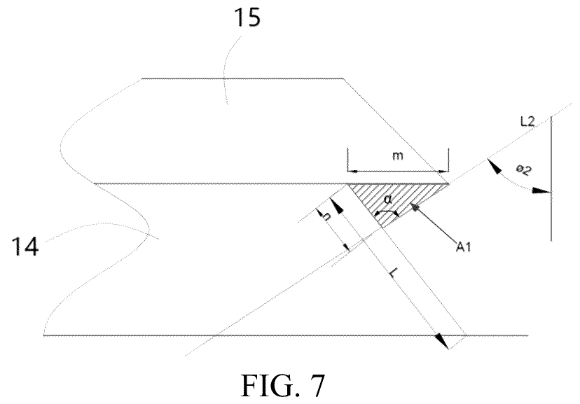

FIG. 7 is a partial schematic diagram of the insulating layer in the first embodiment of the present application, in which, the region A1 is the area where the organic light-emitting layer 16 and the cathode film layer 17 cannot be deposited due to the shielding of the insulating layer 15, m is a width of the insulating layer 15 protruding out from the conductive layer 14, and n is a width of a portion of the conductive layer 14 where the film layer cannot be deposited. According to the sine theorem of a triangular area S1: n/sin(90−ø2)=m/sin(α), it can be obtained that n=mcos(ø2)/sin(α), where ø2 is a film formation angle of the cathode film layer 17, and a is an angle between a boundary line of the film formation of the cathode film layer 17 and a surface of the conductive layer 14. Since the film formation angle ø2 of the cathode film layer 17 remains unchanged, the two angle values do not change. When the value of m becomes smaller, the value of n becomes smaller. When the value of a hypotenuse length L of the conductive layer 14 remains unchanged, the width L-n of the area where the cathode film layer 17 can be deposited will become larger. In such condition, the contact area between the cathode film layer 17 and the conductive layer 14 becomes larger, which is more conducive to control of the display defect.

In some embodiments of the present application, a heat-shrinkable material used for the insulating layer 15 is scandium trifluoride (ScF₃), which has good heat-shrinkable characteristics. After being heated, the insulating layer 15 made of ScF₃ has a narrower width, and the restriction of the end of the insulating layer 15 (that is, the A1 area) on the cathode film layer 17 during deposition becomes smaller, such that a larger cathode film layer 17 can be deposited on the conductive layer 14.

In other embodiments of the present application, the insulating layer 15 may also be made of other heat-shrinkable materials, such as one or more of antimony, bismuth, gallium, bronze, an oxide or a fluoride of antimony, an oxide or a fluoride of bismuth, an oxide or fluoride of gallium, an oxide or a fluoride of bronze, and a heat-shrinkable polymer material

In some embodiments of the present application, the heat-shrinkable polymer material used in the insulating layer 15 is a polyvinyl chloride. In other embodiments of the present application, the heat-shrinkable polymer material can also be one or more of a polyethylene, a polypropylene, a polyester, and a silicone rubber.

In some embodiments of the present application, the composition of the insulating layer 15 includes a non-heat-shrinkable material (such as a thermoplastic materials), in addition to the heat-shrinkable material, as long as the insulating layer 15 prepared by the heat-shrinkable material and the non-heat-shrinkable material can have the function of shrinkage when being heated.

In some embodiments of the present application, the width of the insulating layer 15 protruding out from the conductive layer 14 is any value between 0.2 μm and 1 μm, for example, the width can be 0.3 μm, 0.5 μm, 0.8 μm, 1 μm, and the like, which is not limited in the present application. If the width of the insulating layer 15 protruding out from the conductive layer 14 is too small, the cathode film layer 17 cannot be disconnected, and if the width of the insulating layer 15 protruding out from the conductive layer 14 is too large, the connection area between the cathode film layer 17 and the conductive layer 14 is too small, thereby affecting the conductivity. By limiting the insulating layer 15 protruding out from the conductive layer 14 within the above range, the connection area between the cathode film layer 17 and the conductive layer 14 can be increased as much as possible while ensuring that the cathode film layer 17 is disconnected, and the contact resistance between the cathode film layer 17 and the conductive layer 14 can be reduced.

In some embodiments of the present application, a lateral side of the conductive layer 14 is an inclined surface which is inclined toward the insulating layer 15, and a connection region between the cathode film layer 17 and the conductive layer 14 is located on the inclined surface.

In some embodiments of the present application, as shown in FIG. 3, the lateral side of the conductive layer 14 is an inclined surface which is inclined toward the insulating layer 15, and the connection region between the cathode film layer 17 and the conductive layer 14 is located on the inclined surface. By constructing the lateral side of the conductive layer 14 to be the inclined surface, it is convenient for the cathode film layer 17 to be deposited on the conductive layer 14. In some other embodiments of the present application, the lateral side of the conductive layer 14 is constructed to be a concave curved surface. In other embodiments of the present application, the lateral side of the conductive layer 14 can also be constructed in other forms, which is not limited in the present application.

In some embodiments of the present application, the organic light-emitting layer 16 is not connected to the conductive layer 14. In other embodiments of the present application, the organic light-emitting layer 16 can also be connected to the conductive layer 14, which is not limited in the present application.

In some embodiments of the present application, as shown in FIG. 1, the display panel further includes an organic encapsulation layer 19 and a second inorganic encapsulation layer 20. The organic encapsulation layer 19 is arranged on sides of the inorganic encapsulation layer 18 and the insulating layer 15 away from the substrate 10, and the second inorganic encapsulation layer 20 is arranged on a side of the organic encapsulation layer 19 away from the substrate 10.

In some embodiments of the present application, the inorganic encapsulation layer 18 and the second inorganic encapsulation layer 20 can be made of silicon nitride. In other embodiments of the present application, the inorganic encapsulation layer 18 and the second inorganic encapsulation layer 20 can also be made of silicon oxide, silicon oxynitride, a stacked combination of the above materials, and the like, which is not limited in the present application.

In some embodiments of the present application, the organic encapsulation layer 19 adopts an epoxy resin-based polymer, such as an epoxy resin. In other embodiments of the present application, the organic encapsulation layer 19 may also use other materials, which is not limited in the present application.

In other embodiments of the present application, the cover plate 21 may also be used to replace the inorganic encapsulation layer 18, the organic encapsulation layer 19, and the second inorganic encapsulation layer 20, so as to achieve the encapsulation of the display panel. Optionally, the cover plate 21 may be made of a glass, a resin, or other materials, which is not limited in the present application.

In some embodiments of the present application, as shown in FIG. 1, the inorganic encapsulation layer 18, the organic encapsulation layer 19, the second inorganic encapsulation layer 20, and the cover plate 21 may also be used together to encapsulate the display panel. As shown in FIG. 1, the inorganic encapsulation layer 18, the organic encapsulation layer 19, the second inorganic encapsulation layer 20, and the cover plate 21 are arranged in sequence in a direction away from the substrate 10.

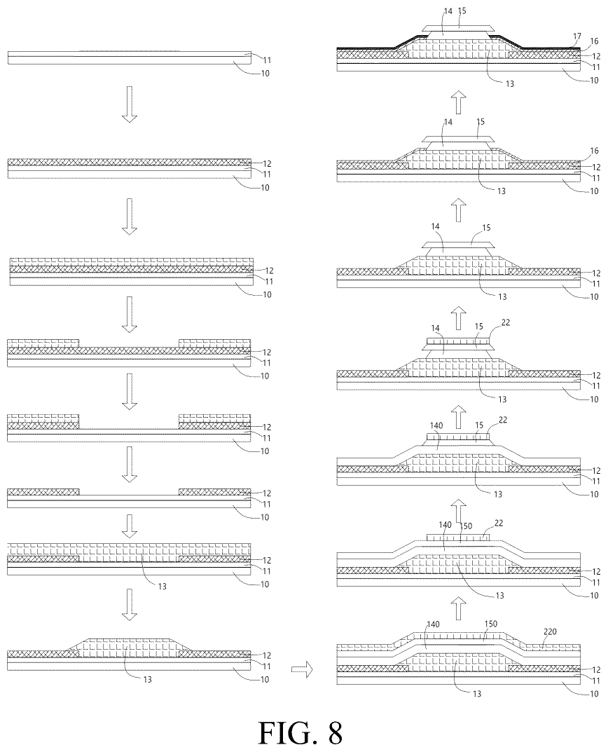

Referring to FIG. 8, a third embodiment of the present application further provides a fabrication method of a display panel, comprising the following steps:
providing a substrate 10;
preparing a driving circuit layer 11 on a side of the substrate 10;
preparing an anode film layer 12 on a side of the driving circuit layer 11 away from the substrate 10, and etching the anode film layer 12 to obtain a plurality of sub-anode film layers 120 arranged at intervals;
preparing a pixel definition layer 13 between adjacent two of the plurality of sub-anode film layers 120;
sequentially preparing a conductive layer 14 and an insulating layer 15 on the pixel definition layer 13, in which, a part of the insulating layer 15 protrudes out from an edge of the conductive layer 14, and the insulating layer 15 is a heat-shrinkable structure layer;
preparing an organic light-emitting layer 16 on the anode film layer 12 and the pixel definition layer 13 by evaporation;
controlling a temperature of the heat-shrinkable structure layer to shrink the heat-shrinkable structure layer and still remain a part of the heat-shrinkable structure layer protrude out from the edge of the conductive layer 14, and preparing a cathode film layer 17 on the organic light-emitting layer 16 and the conductive layer 14; and
preparing an inorganic encapsulation layer 18 on the cathode film layer 17 and the conductive layer 14.

In the fabrication method provided by the present application, heat is generated during the process of evaporating the organic light-emitting layer 16. The heat generated during the evaporation of the organic light-emitting layer 16 can be used to heat the insulating layer 15, so that the insulating layer 15 shrinks under the heat, while a part of the shrunk insulating layer 15 still protrudes out from the edge of the conductive layer 14, so that the projection area of the insulating layer 15 on the lateral side of the conductive layer 14 is reduced while ensuring that the organic light-emitting layer 16 and the cathode film layer 17 are disconnected. Due to the reduction in the projection area, the area covered by the cathode film layer 17 on the lateral side of the conductive layer 14 is increased, that is, the contact area between the cathode film layer 17 and the conductive layer 14 is increased, thereby improving the effect of electrical connection between the cathode film layer 17 and the conductive layer 14. In addition, due to the reduction in the projection area, the difference between the thickness of the inorganic encapsulation layer 18 covering the conductive layer 14 and the thickness of the inorganic encapsulation layer 18 covering the cathode film layer 17 is reduced, thereby ensuring the strength of the inorganic encapsulation layer 18 and reducing the risk of cracks in the inorganic encapsulation layer 18.

In some embodiments of the present application, the driving circuit layer 11 includes a thin film transistor (TFT) stack, an integrated circuit (IC), and a flexible printed circuit (FPC). In other embodiments of the present application, the driving circuit layer 11 may also adopt other structures, as long as a driving voltage for the organic light-emitting layer 16 can be provided. In an embodiment, the driving circuit layer 11 is fabricated on the substrate 10 by photolithography. In other embodiments of the present application, other methods may also be used for fabricating the driving circuit layer 11, which is not limited in the present application.

In some embodiments of the present application, as shown in FIG. 8, the step of preparing the pixel definition layer between adjacent two of the plurality of sub-anode film layers 120 specifically comprises: fabricating a pixel definition layer 13 on the anode film layer 12, exposing and developing the pixel definition layer 13 to form pixel openings on the pixel definition layer 13 above respective sub-anode film layers 120 and keep the pixel definition layer 13 covering edges of the respective sub-anode film layers 120.

In an embodiment, a material of the anode film layer 12 is aluminum. In other embodiments of the present application, the material of the anode film layer 12 may also be silver and an oxide thereof, indium tin oxide (ITO), indium zinc oxide (IZO), a stack of a metal and ITO, or a stack of a metal and IZO. The anode film layer 12 can be deposited on the driving circuit layer 11 by evaporation coating or sputtering coating.

In an embodiment, the pixel definition layer 13 uses a photoresist (PR) layer. In other embodiments of the present application, the pixel definition layer 13 can also use an inorganic film, such as silicon nitride, silicon oxide, silicon oxynitride, and the like.

In some embodiments of the present application, the cathode film layer 17 may be formed on the surface of the organic light-emitting layer 16 and the conductive layer 14 by an evaporation coating process. In other embodiments of the present application, the cathode film layer 17 may also be formed by vacuum sputtering coating or other processes, which is not limited in the present application.

In some embodiments of the present application, in order to ensure that the heat shrinkage of the insulating layer 15 meets the requirements, the insulating layer 15 is heated before the cathode film layer 17 is formed after the organic light-emitting layer 16 is evaporated, so as to ensure that the insulating layer 15 has sufficient heat accumulation, thereby achieving the best heat shrinkage.

In some embodiments of the present application, after the organic light-emitting layer 16 is evaporated, the display panel can be placed on a heating platform for heating. The contact surface can be the surface where the insulating layer 15 is located, or it can be the surface away from the insulating layer 15 (that is, the surface where the substrate 10 is located).

In some embodiments of the present application, a temperature of the insulating layer 15 in preparation of the organic light-emitting layer 16 is lower than a temperature of the insulating layer 15 in preparation of the cathode film layer 17. By controlling the temperature of the insulating layer 15, it can be ensured that during the preparation of the organic light-emitting layer 16, the organic light-emitting layer 16 can cover as little as possible on the conductive layer 14, while the cathode film layer 17 can cover as much as possible on the conductive layer 14.

In some embodiments of the present application, after the heat shrinkage of the insulating layer 15, a width of the part the insulating layer 15 protruding out from the edge of the conductive layer 14 is 0.2 μm to 1 μm. Within this range, the connection area between the cathode film layer 17 and the conductive layer 14 can be increased as much as possible while ensuring that the cathode film layer 17 is disconnected, and the contact resistance between the cathode film layer 17 and the conductive layer 14 can be reduced.

In some embodiments of the present application, as shown in FIG. 5, L1 is a film-forming boundary line of the organic light-emitting layer 16, ø1 is a film formation angle (that is, the evaporation angle) of the organic light-emitting layer 16, L2 is a film-forming boundary line of the cathode film layer 17, and ø2 is the film formation angle of the cathode film layer 17. When preparing the organic light-emitting layer 16 and the cathode film layer 17, ø1 is controlled to be smaller than ø2 (the film formation angle can be controlled by adjusting the evaporation device), so that a coverage area of the cathode film layer 17 is greater than a coverage area of the organic light-emitting layer 16, and the organic light-emitting layer 16 is prevented from affecting the connection between the cathode film layer 17 and the conductive layer 14.

In some embodiments of the present application, referring to FIG. 8, sequentially preparing the conductive layer 14 and the insulating layer 15 on the pixel definition layer 13 specifically includes:
covering the sub-anode film layer 120 and the pixel definition layer 13 with a pre-conductive layer 140, a pre-insulating layer 150, and a pre-protective layer 220 stacked in sequence;
performing local dry etching on the pre-protective layer 220 to obtain a protective layer 22 corresponding to the pixel definition layer 13;
performing wet etching on the pre-insulating layer 150 to obtain the insulating layer 15 located between the protective layer 22 and the pre-conductive layer 140;
performing wet etching on the pre-conductive layer 140 to obtain the conductive layer 14 located between the insulating layer 15 and the pixel definition layer 13; and
removing the protective layer 22.

In some embodiments of the present application, the pre-conductive layer may be a metal, such as molybdenum, aluminum, nickel, silver, or a stack of one or more of these metals, or an oxide, alloy, etc. thereof, which is not limited in the present application.

In some embodiments of the present application, the pre-conductive layer may be deposited on the anode film layer 12 and the pixel definition layer 13 by a physical vapor deposition (PVD) method, such as vacuum evaporation coating, vacuum sputtering coating, and vacuum ion coating.

In some embodiments of the present application, if the pre-insulating layer is made of an inorganic material, the pre-insulating layer may be deposited on the pre-conductive layer by chemical vapor deposition, and if the pre-insulating layer is made of organic material, the pre-insulating layer may be coated on the pre-conductive layer by spray coating.

In some embodiments of the present application, the protective layer 22 may be a PR layer, and the PR layer may be removed by a commonly used removal method in the prior art, which is not limited in the present application.

The above description is only preferred embodiments of the present application and is not intended to limit the present application. Any modifications, equivalent replacements, and improvements made within the spirit and principles of the present application shall be included within the protection scope of the present application.

What is claimed is:

1. A display panel, comprising:
a substrate;
a driving circuit layer, which is located on a side of the substrate;
an anode film layer, which comprises a plurality of sub-anode film layers arranged at intervals on a side of the driving circuit layer away from the substrate;
a pixel definition layer, which is arranged between adjacent two of the plurality of sub-anode film layers;
a conductive layer, which is arranged on a side of pixel definition layer away from the substrate;
an insulating layer, which is arranged on a side of the conductive layer away from the pixel definition layer, has a part thereof protruding out from an edge of the conductive layer to form an eave structure, and is a heat-shrinkable structure layer;
an organic light-emitting layer, which is arranged on the anode film layer and the pixel definition layer;
a cathode film layer, which is arranged on the organic light-emitting layer and covers a part of a lateral side of the conductive layer, has a part thereof located within a projection area of the insulating layer along a thickness direction of the insulating layer; and
an inorganic encapsulation layer, which is arranged on the cathode film layer and the conductive layer.

2. The display panel according to claim 1, wherein a width of a side of the insulating layer away from the conductive layer is greater than a width of a side of the insulating layer close to the conductive layer.

3. The display panel according to claim 2, wherein a cross section of the insulating layer in a thickness direction of the insulating layer is a trapezoid, and a width of the insulating layer gradually increases in a direction away from the conductive layer.

4. The display panel according to claim 3, wherein a lateral side of the insulating layer is an inclined surface having an inclination angle of 20° to 70°.

5. The display panel according to claim 1, wherein the heat-shrinkable structure layer comprises a heat-shrinkable material, and the heat-shrinkable material comprises at least one of antimony, bismuth, gallium, bronze, scandium trifluoride, an oxide or a fluoride of antimony, an oxide or a fluoride of bismuth, an oxide or a fluoride of gallium, an oxide or a fluoride of bronze, and a heat-shrinkable polymer material.

6. The display panel according to claim 5, wherein the heat-shrinkable polymer material comprises at least one of a polyvinyl chloride, a polyethylene, a polypropylene, a polyester, and a silicone rubber.

7. The display panel according to claim 1, wherein a width of the part of the insulating layer protruding out from the edge of the conductive layer is 0.2 μm to 1 μm.

8. The display panel according to claim 1, wherein the lateral side of the conductive layer is an inclined surface.

9. The display panel according to claim 8, wherein the lateral side of the conductive layer is an inclined surface which is inclined toward a side of the insulating layer, and a connection region between the cathode film layer and the conductive layer is located on the inclined surface.

10. The display panel according to claim 1, wherein the display panel further comprises an organic encapsulation layer and a second inorganic encapsulation layer; the organic encapsulation layer is arranged on sides of the inorganic encapsulation layer and the insulating layer away from the substrate; and the second inorganic encapsulation layer is arranged on a side of the organic encapsulation layer away from the substrate.

11. The display panel according to claim 10, wherein the display panel further comprises a cover plate; and the inorganic encapsulation layer, the organic encapsulation layer, the second inorganic encapsulation layer, and the cover plate are arranged in sequence in a direction away from the substrate.

12. A fabrication method for a display panel, comprising:
providing a substrate;
preparing a driving circuit layer on a side of the substrate;
preparing an anode film layer on a side of the driving circuit layer away from the substrate, and etching the anode film layer to obtain a plurality of sub-anode film layers arranged at intervals;
preparing a pixel definition layer between adjacent two of the plurality of sub-anode film layers;
sequentially preparing a conductive layer and an insulating layer on the pixel definition layer, in which, a part of the insulating layer protrudes out from an edge of the conductive layer, and the insulating layer is a heat-shrinkable structure layer;
preparing an organic light-emitting layer on the anode film layer and the pixel definition layer by evaporation;
controlling a temperature of the heat-shrinkable structure layer to shrink the heat-shrinkable structure layer and still remain a part of the heat-shrinkable structure layer protrude out from the edge of the conductive layer, and preparing a cathode film layer on the organic light-emitting layer and the conductive layer; and
preparing an inorganic encapsulation layer on the cathode film layer and the conductive layer.

13. The fabrication method for the display panel according to claim 12, wherein before forming the cathode film layer, the heat-shrinkable structure layer is subjected to a heating treatment to shrink the heat-shrinkable structure layer.

14. The fabrication method for the display panel according to claim 12, wherein a film formation angle when preparing the organic light-emitting layer is smaller than a film formation angle when preparing the cathode film layer.

15. The fabrication method for the display panel according to claim 12, wherein a temperature of the insulating layer in preparation of the organic light-emitting layer is lower than a temperature of the insulating layer in preparation of the cathode film layer.

16. The fabrication method for the display panel according to claim 12, wherein after the heat shrinkage of the insulating layer, a width of the part of the insulating layer protruding out from the edge of the conductive layer is 0.2 μm to 1 μm.

17. The fabrication method for the display panel according to claim 12, wherein the step of sequentially preparing the conductive layer and the insulating layer on the pixel definition layer comprises:
covering the sub-anode film layer and the pixel definition layer with a pre-conductive layer, a pre-insulating layer, and a pre-protective layer stacked in sequence;
performing local dry etching on the pre-protective layer to obtain a protective layer corresponding to the pixel definition layer;
performing wet etching on the pre-insulating layer to obtain the insulating layer located between the protective layer and the pre-conductive layer;
performing wet etching on the pre-conductive layer to obtain the conductive layer located between the insulating layer and the pixel definition layer; and
removing the protective layer.
